(19) United States
(12) Patent Application Publication
(10) Pub. No.: US 2016/0128210 A1
(43) Pub. Date: May 5, 2016

(54) MAGNETIC ATTRACTION-FIXING ASSEMBLY AND A ROTATING SUPPORT STRUCTURE FOR A PORTABLE DEVICE HAVING THE MAGNETIC ATTRACTION-FIXING ASSEMBLY

(71) Applicant: Bing-Zhang LEE, Taipei City (TW)

(72) Inventor: Bing-Zhang LEE, Taipei City (TW)

(21) Appl. No.: 14/533,169

(22) Filed: Nov. 5, 2014

(51) Int. Cl. H05K 5/02; F16B 1/00

(52) U.S. Cl. CPC H05K 5/0204; F16B 1/00; F16B 2001/0035

(57) ABSTRACT

Provided is a magnetic attraction-fixing assembly and a rotating support structure for a portable device. The magnetic attraction-fixing assembly comprises two magnetic units, the two magnetic units stacked with and attracting each other; wherein each of the magnetic units respectively comprises a circular magnetic component and at least one annular magnetic component around the circular magnetic component, a magnetic pole of the circular plane of the circular magnetic component is an unlike pole to a magnetic pole of an annular plane of the annular magnetic component that is adjacent to the circular magnetic component. The rotating support structure comprises two magnetic units and a body. Magnetic attractions in both radial and axial directions are enhanced.

### BACKGROUND OF THE INVENTION

1. Field of the Invention

The present invention relates to a magnetic attraction-fixing assembly, particularly to a magnetic attraction-fixing assembly having a circular magnetic component and at least one annular magnetic component around the circular magnetic component, and the poles of the adjacent planes of the magnetic components are unlike poles. The present invention also relates to a rotating support structure for a portable device having the magnetic attraction-fixing assembly as an attracting and rotating component.

2. Description of the Prior Arts

For the convenience in portability or to protect the tablet PC, a user usually buys a protective cover to cover the tablet PC. However, when the tablet PC is put into the protective cover, the increased weight will become a burden to the user's hands. A quickly removable protective cover is thus needed.

As shown in FIG. 8, a circular and flat magnet 70 of the prior art has a south pole at one side and a north pole at the other side. As shown in FIG. 9, the rotating and removable support structure of the portable device has a protective cover body 80 and a cover body 90, and the protective cover body 80 comprises a retaining tab 81 having a first circular magnetic component 811 and a first buckle 812. The portable device is put into the back side of the cover body 90, which has a second circular magnetic component 91 and a second buckle 92, wherein the second circular magnetic component 91 attracts the first circular magnetic component 811, and the second buckle 92 buckles to the first buckle 812. The portable device placed in the protective cover body 80 can be rotated, and the protective cover body 80 and the cover body 90 can be separated depending on the user's need.

However, in the above prior art as shown in FIG. 9, the magnetic structure does not consider the properties of magnetic field lines. The circular magnetic components can hardly provide a magnetic attraction force for radial positioning, so that the first buckle 812 and the second buckle 92 are implemented in order to prevent the cover body 90 from radial sliding and detaching from the protective cover body 80 when the first circular magnetic component 811 attracts the second circular magnetic component 91. This approach will increase thickness and weight of the protective cover body 80 and the cover body 90; however, the protective cover body 80 and the cover body 90 are still prone to risk of separation.

FIG. 10 shows another conventional magnetic component commonly used on bags or clothes. In order to solve the problem that the circular magnetic component cannot provide the radial positioning, the middle of a first magnetic component 98 is usually milled with a groove 981 and the middle of a second magnetic component 99 has a tenon 991 fitted to the groove 981 of the first magnetic component 98 when attracted to each other for increasing the stability of radial positioning. But, either the groove 981 milled at the first magnetic component 98 or the tenon 991 mounted to the second magnetic component 99 will increase the thickness of the magnetic components. Therefore, the prior art still has disadvantages to be solved.

### SUMMARY OF THE INVENTION

According to the above description, the present invention provides a circular magnetic component and at least one annular magnetic component around the circular magnetic component, and each two adjacent poles of the same plane of the magnetic components are unlike poles, so as to improve the positioning strength of the magnetic attraction-fixing assembly, which is better than the circular magnet of the prior art.

The objective of the invention is to provide a magnetic attraction-fixing assembly comprising two magnetic units, each magnetic unit formed in a rounded and flat shape, the two magnetic units stacked with and attracting each other; wherein each of the magnetic units respectively comprises a circular magnetic component and at least one annular magnetic component around the circular magnetic component, each circular magnetic component comprises a circular plane and each annular magnetic component comprises an annular plane; the circular plane of each circular magnetic component and the annular plane of each annular magnetic component are located at the same plane, a magnetic pole of the circular plane of the circular magnetic component is an unlike pole to a magnetic pole of the annular plane of the annular magnetic component that is adjacent to the circular magnetic component.

Preferably, each of the magnetic units respectively comprises multiple annular magnetic components, the annular magnetic components surround the circular magnetic component concentrically and sequentially away from the center of the circular magnetic component, the circular plane of the circular magnetic component and the annular planes of the annular magnetic components are located at the same plane; each two adjacent poles of the annular planes of the annular magnetic components are unlike poles.

Preferably, a diameter of the circular magnetic component is smaller than an inner diameter of the annular magnetic component.

Preferably, the magnetic units further comprise at least one cap which covers one of the magnetic units, and the at least one cap is made of metal. In another aspect, the present invention also provides a rotating support structure for a portable device, and the magnetic attraction-fixing assembly comprises two magnetic units and a body. The two magnetic units are stacked with and attract each other. The body comprises a bottom, a support sheet, a carrying sheet and a cover. The support sheet comprises two opposite sides, wherein one of the sides is connected to the bottom; the carrying sheet is connected to the other side of the support sheet; the carrying sheet has a first circular hole, wherein one of the magnetic units is embedded in the first circular hole; and the cover is connected to a side of the carrying sheet and has a second circular hole, wherein the other magnetic unit is embedded in the second circular hole.

Preferably, a diameter of the circular magnetic component is smaller than an inner diameter of the annular magnetic component.

Preferably, the magnetic units further comprise at least one cap which covers one of the magnetic units, and the at least one cap is made of metal.

Preferably, the diameters of the magnetic units are respectively smaller than the diameter of the first circular hole of the carrying sheet and the diameter of the second circular hole of the cover.

Preferably, a first folding line is disposed on the support sheet and the bottom.

Preferably, a second folding line is disposed on the carrying sheet and the support sheet.

Preferably, the body further comprises a first retaining tab located between the carrying sheet and the cover.

Preferably, the body further comprises a second retaining tab located at a plane of one of the magnetic units that is mounted in the second circular hole of the cover and is opposite to another plane of said magnetic unit that is attracted to the other magnetic unit mounted in the first hole.

The advantages of the present invention are:

1. Compared to the circular magnet of the prior art, the capability of radial positioning of the present invention is better than the circular magnet of the prior art under the same thickness, weight and purity of magnet.

2. The magnetic unit of the present invention adopts the principle that unlike poles attract each other and like poles repel each other, and magnetic attractions in both radial and axial directions are greatly increased, such that the present invention has excellent capability in fixing and positioning objects.

3. The magnetic unit of the present invention is thin. Without additional buckle, the portable device can be fixed on the body of the cover, or can be placed onto the joystick for stabilizing the object and saving effort.

4. The more annular magnetic components of the present invention are used, the stronger attraction and positioning against displacement can be achieved.

5. For manufacture, the thickness can be reduced because the magnetic units of the present invention do not need the tenon and the groove.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of one of the magnetic units of the present invention;

FIG. 2 is a cross-sectional view of the magnetic units;

FIG. 3 is a cross-sectional view of the magnetic units and the cap;

FIG. 4 is a top view of another magnetic unit of the present invention;

FIG. 5 is an exploded view of the preferred embodiment of the rotating support structure for a portable device;

FIG. 6 illustrates a cross-sectional view and operational view of the preferred embodiment of the rotating support structure for a portable device;

FIG. 7 illustrates an operational view of the preferred embodiment of the rotating support structure embedded in the joystick of the present invention;

FIG. 8 is a perspective view of the magnetic attraction-fixing assembly in accordance with the prior art;

FIG. 9 is a perspective view of the rotating support structure for a portable device in accordance with the prior art; and

FIG. 10 is a perspective view of another magnetic attraction-fixing assembly in accordance with the prior art.

### DETAILED DESCRIPTION OF THE PREFERRED EMBODIMENTS

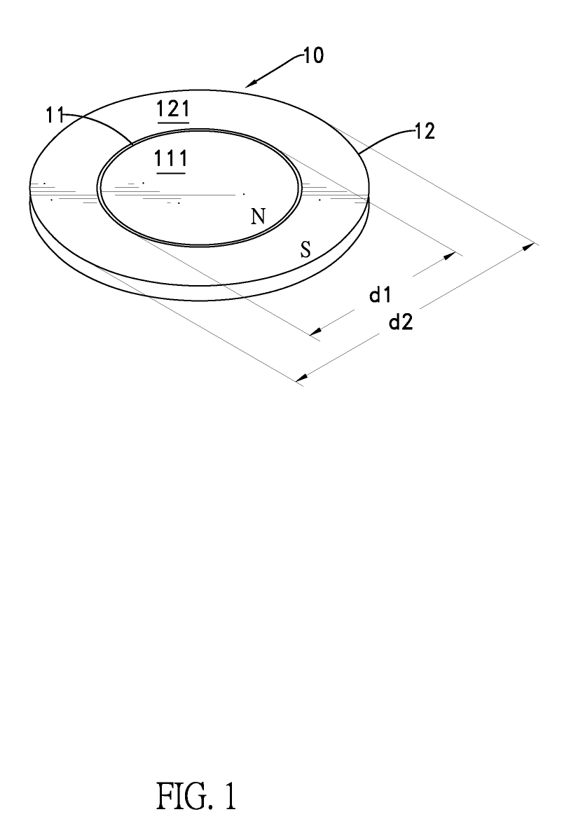

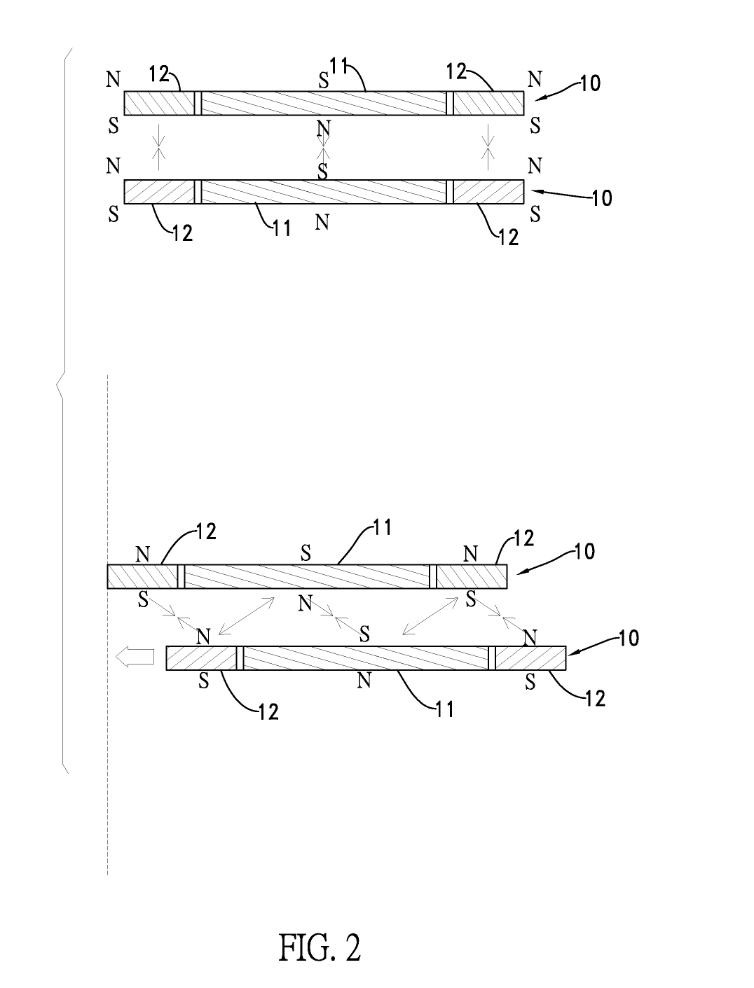

As shown in FIGS. 1 and 2, the present invention provides a magnetic attraction-fixing assembly comprising two magnetic units 10, wherein each magnetic unit 10 is formed in a rounded and flat shape, and the two magnetic units 10 are stacked with and attract each other; wherein each of the magnetic units 10 respectively comprises a circular magnetic component 11 and at least one annular magnetic component 12 around the circular magnetic component 11. Each one of the at least one annular magnetic component 12 has an inner diameter d1 and an outer diameter d2. Each circular magnetic component 11 comprises a circular plane 111 and each annular magnetic component 12 comprises an annular plane 121; the circular plane 111 of each circular magnetic component 11 and the annular plane 121 of each annular magnetic component 12 are located at the same plane, a magnetic pole of the circular plane 111 of the circular magnetic component 11 is an unlike pole to a magnetic pole of the annular plane 121 of the annular magnetic component 12 that is adjacent to the circular magnetic component 11. A diameter of the circular magnetic component 11 is smaller than the inner diameter d2 of the annular magnetic component 12.

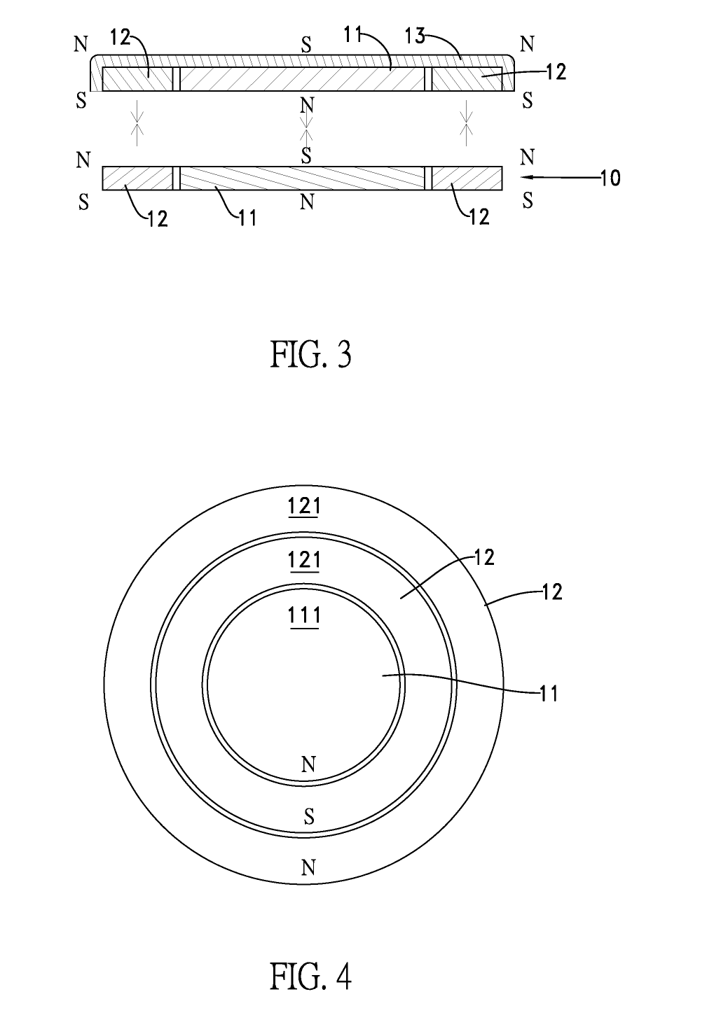

As shown in FIG. 3, in a preferred embodiment, the magnetic units 10 further comprise at least one cap 13 which covers one of the magnetic units 10, and the at least one cap 13 is made of metal. When the at least one cap 13 covers the magnetic unit 10, the cap 13 can concentrate the magnetic field lines to increase the magnetic attraction. In another preferred embodiment, the magnetic units 10 comprise two caps 13, which respectively cover the two magnetic units 10.

As shown in FIG. 4, in another preferred embodiment, each of the magnetic units 10 respectively comprises multiple annular magnetic components 12, the annular magnetic components 12 surround the circular magnetic component 11 concentrically and sequentially away from the center of the circular magnetic component, the circular plane 111 of the circular magnetic component 11 and the annular planes 121 of the annular magnetic components 12 are located at the same plane; each two adjacent poles of the annular planes 121 of the annular magnetic components 12 are unlike poles.

As shown in FIG. 2, when the present invention is in use, the two magnetic units 10 can attract each other by the magnetic force. When radial displacement occurs between the two magnetic units 10 due to external force, the magnetic pole of the contact surface of the circular magnetic component 11 of one of the magnetic units 10 is identical to the magnetic pole of the contact surface of the annular magnetic component 12 of the other magnetic unit 10 to generate repulsive force to resist displacement. Therefore, the present invention significantly enhances the positioning stability of the magnetic units 10 via the principle that like magnetic poles repel each other.

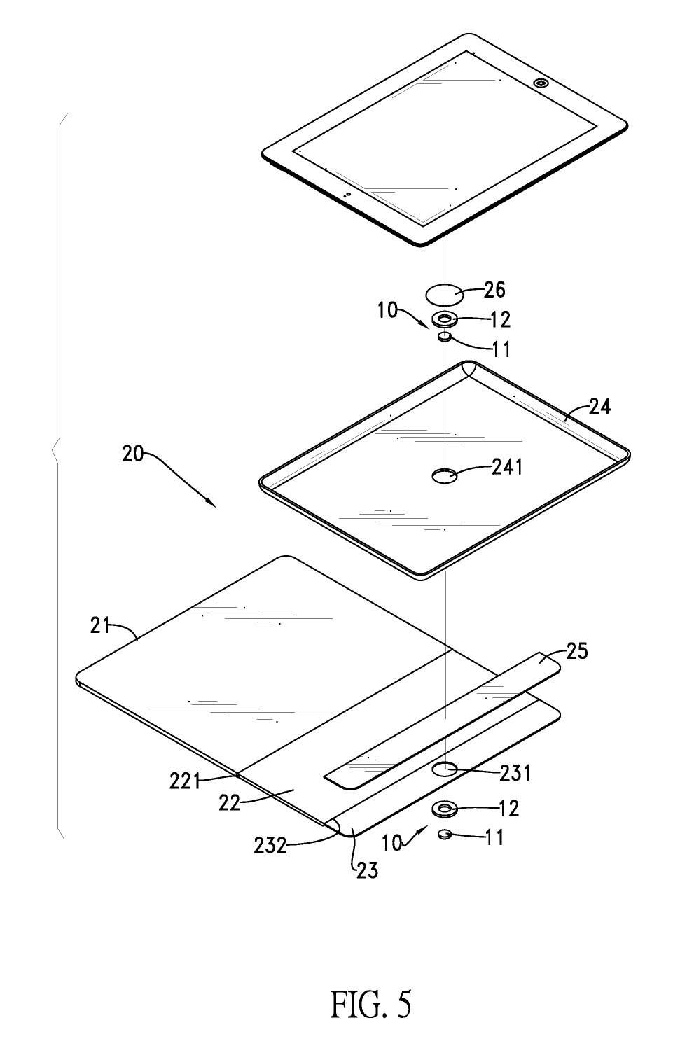

As shown in FIG. 5, the present invention provides a rotating support structure for a portable device, and the rotating support structure comprises the above said two magnetic units 10 and a body 20.

The two magnetic units 10 are stacked with and attract each other. The diameter of the circular magnetic component 11 is smaller than the inner diameter of the annular magnetic component 12. In a preferred embodiment, the magnetic units 10 further comprise at least one cap 13 covering one of the magnetic units 10.

The body 20 comprises a bottom 21, a support sheet 22, a carrying sheet 23 and a cover 24. The bottom 21, the support sheet 22, and the carrying sheet 23 are aligned sequentially. The bottom 21 is a rectangular structure; wherein a first folding line 221 is disposed between the support sheet 22 and the bottom 21. The support sheet 22 has two opposite sides, one of the sides is connected to the bottom 21, and the other side is connected to the carrying sheet 23. The carrying sheet 23 has a first circular hole 231, such that one of the magnetic units 10 is embedded in the first circular hole 231. A second folding line 232 is disposed on the carrying sheet 23 and the support sheet 22. The cover 24 is connected to a side of the carrying sheet 23 and has a second circular hole 241, and the other magnetic unit 10 is embedded in the second circular hole 241. The diameters of the magnetic units 10 are respectively smaller than a diameter of the first circular hole 231 of the carrying sheet 23 and a diameter of the second circular hole 241 of the cover 24.

In another preferred embodiment, the body 20 further comprises a first retaining tab 25 comprising a thin and high-strength material and located between the carrying sheet 23 and the cover 24. The thin and high-strength material is, but not limited to, carbon-fiber plate. In another preferred embodiment, the body 20 further comprises a second retaining tab 26 located at a plane of one of the magnetic units 10 that is mounted in the second circular hole 241 of the cover 24 and is opposite to another plane of said magnetic unit 10 that is attracted to the other magnetic unit 10 mounted in the first hole 231. The second retaining tab 26 comprises a thin and high-strength material which is, but not limited to, plastic, poly-carbon, fiberglass, carbon fiber and metal.

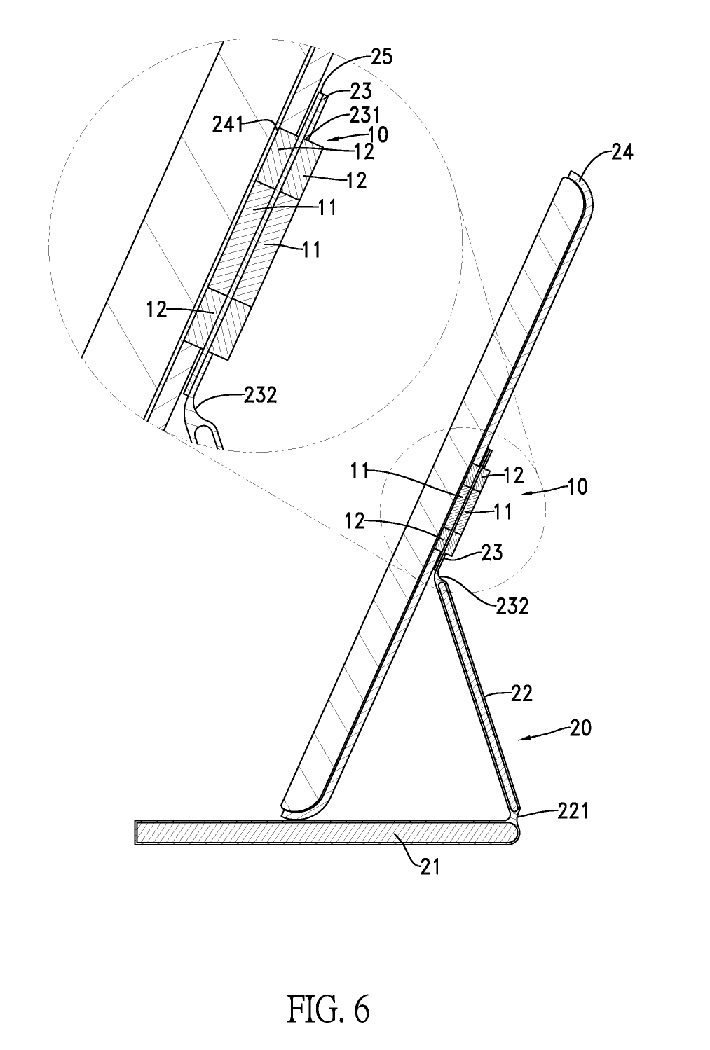

As shown in FIG. 6, when the present invention is in use, a portable electronic device is put into the cover 24. One of the magnetic units 10 that is fitted in the second circular hole 241 of the cover 24 magnetically attracts the other magnetic unit 10 which is fitted in the first circular hole 231 of the carrying sheet 23 to combine both the cover 24 and the carrying sheet 23. The first folding line 221 of the support sheet 22 and the second folding line 232 of the carrying sheet 23 can be folded, and a side of the portable electronic device can be placed on the bottom 21 for supporting and erecting the portable electronic device. Because of magnetic attraction of the support structure, an angle of the magnetic units 10 can be easily adjusted to vertical or lateral reading model. When a user handles the portable electronic device, the body 20 can be separated from the portable electronic device if the user wants to reduce the weight for handling. When a user wants to change the color of the body 20 or the body 20 has Bluetooth wireless keyboard, the body 20 can be changed directly to the desired color without removing the cover 24.

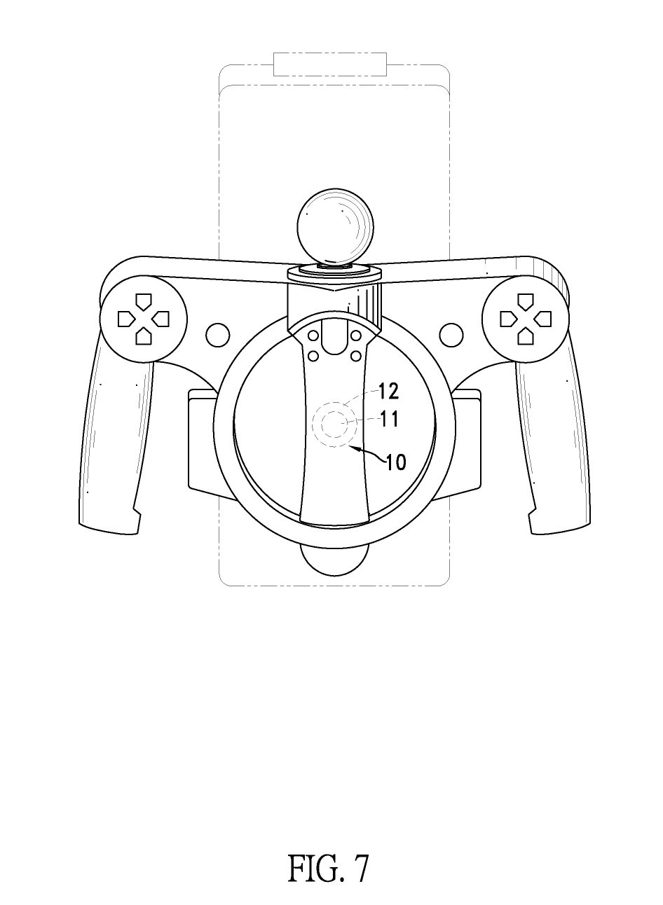

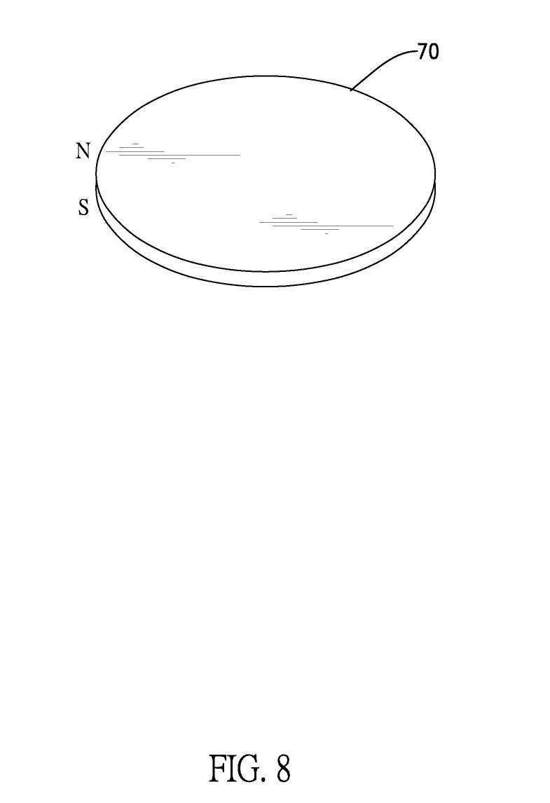

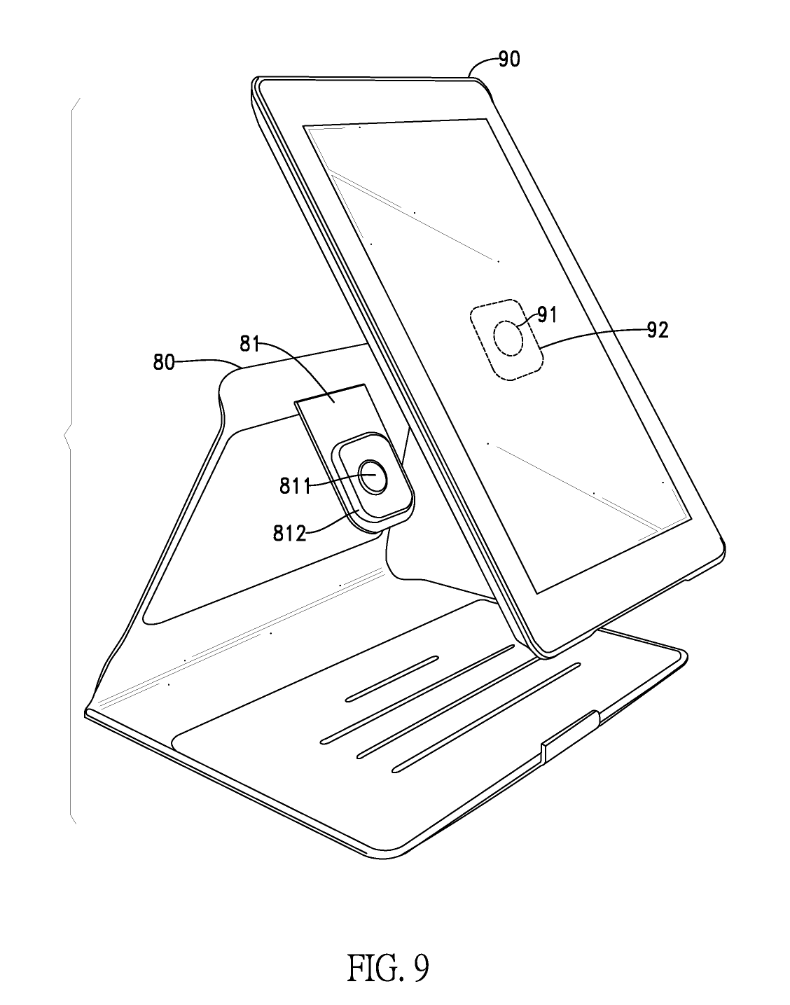

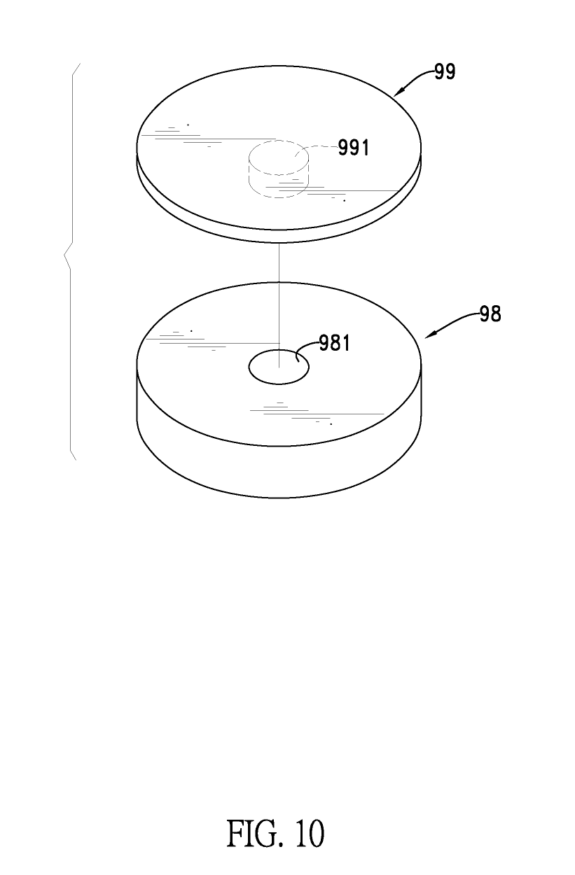

As shown in FIG. 7, in another preferred embodiment, when a game joystick has one of the magnetic units 10 at the back, and the support seat of the joystick has the other magnetic unit 10, a user can easily rotate the joystick, which is attracted to the support seat by the magnetic unit 10 for relieving hand pain caused by manually lifting the joystick. Also, the magnetic attraction-fixing assembly of the present invention can generate repulsive force to resist displacement for avoiding the separation of the joystick and the support seat during intense gaming exercise. The magnetic units 10 can be used on two objects that may be selectively fixed or separated, or an object that needs to be fixed to or separated from a wall, a car, a bag, etc.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

1. A magnetic attraction-fixing assembly, comprising:
two magnetic units, each magnetic unit formed in a rounded flat shape, the two magnetic units stacked with and attracting each other; wherein each of the magnetic units respectively comprises a circular magnetic component and at least one annular magnetic component around the circular magnetic component, each circular magnetic component comprises a circular plane and each annular magnetic component comprises an annular plane; the circular plane of each circular magnetic component and the annular plane of each annular magnetic component are located at the same plane, a magnetic pole of the circular plane of the circular magnetic component is an unlike pole to a magnetic pole of the annular plane of the annular magnetic component that is adjacent to the circular magnetic component.

2. The magnetic attraction-fixing assembly according to claim 1, wherein each of the magnetic units respectively comprises multiple annular magnetic components, the annular magnetic components surround the circular magnetic component concentrically and sequentially away from the center of the circular magnetic component, the circular plane of the circular magnetic component and the annular planes of the annular magnetic components are located at the same plane; each two adjacent poles of the annular planes of the annular magnetic components are unlike poles.

3. The magnetic attraction-fixing assembly according to claim 1, wherein a diameter of the circular magnetic component is smaller than an inner diameter of the annular magnetic component.

4. The magnetic attraction-fixing assembly according to claim 2, wherein a diameter of the circular magnetic component is smaller than an inner diameter of the annular magnetic component.

5. The magnetic attraction-fixing assembly according to claim 1, wherein the magnetic units further comprise at least one cap which covers one of the magnetic units, and the at least one cap is made of metal.

6. The magnetic attraction-fixing assembly according to claim 2, wherein the magnetic units further comprise at least one cap which covers the magnetic units, and the at least one cap is made of metal.

7. A rotating support structure for a portable device, comprising;
the magnetic attraction-fixing assembly according to claim 1, the two magnetic units stacked with and attracting each other; and
a body, comprising
a bottom;
a support sheet comprising two opposite sides, wherein one of the sides is connected to the bottom;
a carrying sheet connected to the other side of the support sheet; the carrying sheet having a first circular hole, wherein one of the magnetic units is embedded in the first circular hole; and
a cover connected to a side of the carrying sheet and having a second circular hole, wherein the other magnetic unit is embedded in the second circular hole.

8. The rotating support structure for a portable device according to claim 7, wherein a diameter of the circular magnetic component is smaller than an inner diameter of the annular magnetic component.

9. The rotating support structure for a portable device according to claim 7, wherein the magnetic units further comprise at least one cap which covers one of the magnetic units, and the at least one cap is made of metal.

10. The rotating support structure for a portable device according to claim 8, wherein the magnetic units further comprise at least one cap which covers one of the magnetic units, and the at least one cap is made of metal.

11. The rotating support structure for a portable device according to claim 7, wherein diameters of the magnetic units are respectively smaller than a diameter of the first circular hole of the carrying sheet and a diameter of the second circular hole of the cover.

12. The rotating support structure for a portable device according to claim 7, wherein a first folding line is disposed on the support sheet and the bottom.

13. The rotating support structure for a portable device according to claim 7, wherein a second folding line is disposed on the carrying sheet and the support sheet.

14. The rotating support structure for a portable device according to claim 7, wherein the body further comprises a first retaining tab located between the carrying sheet and the cover.

15. The rotating support structure for a portable device according to claim 7, wherein the body further comprises a second retaining tab located at a plane of one of the magnetic units that is mounted in the second circular hole of the cover and is opposite to another plane of said magnetic unit that is attracted to the other magnetic unit mounted in the first hole.
